(19) United States
(12) Patent Application Publication
(10) Pub. No.: US 2014/0261155 A1
(43) Pub. Date: Sep. 18, 2014

(54) CRUCIBLE FOR CONTROLLING OXYGEN AND RELATED METHODS

(71) Applicant: MEMC ELECTRONIC MATERIALS, INC., St. Peters, MO (US)

(72) Inventors: Steve L. Kimbel, O'Fallon, MO (US); Steve John Ferguson, Scappoose, OR (US)

(21) Appl. No.: 13/837,092

(22) Filed: Mar. 15, 2013

(51) Int. Cl. C30B 15/12; C30B 15/00

(52) U.S. Cl. CPC C30B 15/12; C30B 15/002
USPC 117/31; 117/213

(57) ABSTRACT

A system for growing a crystal ingot from a melt includes a first crucible, a second crucible, and a weir. The first crucible has a first base with a top surface and a first sidewall that form a first cavity. The second crucible is located within the first cavity of the first crucible, and has a second base and a second sidewall that form a second cavity. The second base has a bottom surface that is shaped to allow the second base to rest against the top surface of the first base. The second crucible includes a crucible passageway to allow movement of the melt therethrough. The weir is located inward from the second sidewall to inhibit movement of the melt from a location outward of the weir to a location inward of the weir.

### FIELD

This disclosure generally relates to systems and methods for the production of ingots of semiconductor or solar material and more particularly to systems and methods for reducing dislocations in the ingot by limiting or inhibiting particle generation and transport within a silicon melt.

### BACKGROUND

In the production of single silicon crystals grown by the Czochralski (CZ) method, polycrystalline silicon is first melted within a crucible, such as a quartz crucible, of a crystal pulling device to form a silicon melt. The puller then lowers a seed crystal into the melt and slowly raises the seed crystal out of the melt, solidifying the melt onto the seed crystal. To produce a single high quality crystal using this method, particle density of foreign particles such as solid quartz from the continuously dissolving quartz melt support (or quartz crucible) in the liquid silicon must be very low adjacent to the solidifying crystal. Prior systems for accomplishing this goal have not been completely satisfactory. Thus, there exists a need for a more efficient and effective system and method to limit solid quartz particles immediately adjacent to the ingot.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

A first aspect is a system for growing a crystal ingot from a melt. The system includes a first crucible, a second crucible, and a weir. The first crucible has a first base and a first sidewall that form a first cavity for containing the melt. The first base has a top surface. The second crucible is located within the first cavity of the first crucible and has a second base and a second sidewall. The second sidewall is sized for placement within the first cavity of the first crucible. The second base and the second sidewall form a second cavity. The second base has a bottom surface that is shaped to allow the second base to rest against the top surface of the first base. The second crucible includes a crucible passageway therethrough to allow the melt in the first cavity of the first crucible to move into the second cavity of the second crucible. The weir is located along the second base of the second crucible at a location inward from the second sidewall to inhibit movement of the melt from a location outward of the weir to a location inward of the weir.

Another aspect is a system for growing a crystal ingot from a melt. The system includes a first crucible, a second crucible, a weir, and a heat reflector. The first crucible has a first base and a first sidewall that form a first cavity for containing the melt. The second crucible is located within the first cavity of the first crucible and has a second base and a second sidewall. The second sidewall is sized for placement within the first cavity of the first crucible. The second base and the second sidewall form a second cavity. The second crucible includes a crucible passageway therethrough to allow the melt in the first cavity of the first crucible to move into the second cavity of the second crucible. The weir is located within the second cavity of the second crucible to inhibit movement of the melt from a location outward of the weir to a location inward of the weir. The heat reflector has a leg extending downward between the second sidewall of the second crucible and the weir to form a tortuous gas and particle path between an inner area being inward of the weir to an outer area being outward of the second sidewall.

Another aspect is a method for growing a crystal ingot from a melt in a crystal growing system that includes a crucible having a base and a first wall and a second wall extending upward from the base. The second wall is located inward from the first wall. The second wall has a passageway to allow the melt to move therethrough. The crucible defines a first cavity between the first wall and the second wall and a second cavity inward of the second wall.

The method includes placing a weir within the second cavity to inhibit movement of the melt from a location outward of the weir to a location inward of the weir, placing feedstock material into the first cavity of the crucible, melting the feedstock material to form the melt to allow movement of the melt from the first cavity into the second cavity and inward of the weir, and biasing oxygen upwards on the melt with argon at a pressure of between about 15 and about 70 Torr.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a cross-sectional view of a crystal growing system in accordance with one embodiment; and

FIG. 2 is an enlarged cross-sectional view of a crucible assembly of FIG. 1.

Corresponding reference characters indicate corresponding parts throughout the several views of the drawings.

### DETAILED DESCRIPTION

Referring to FIG. 1, a crystal growing system is shown schematically and is indicated generally at 100. Note that portions of the system, particularly the furnace or puller enclosure, insulation, and susceptor support mechanisms, are omitted for clarity. The crystal growing system 100 may be used to produce a single crystal ingot by a Czochralski method.

As discussed herein, the system is described in relation to the continuous Czochralski method of producing single crystal ingots, though a batch process may be used. However, the system disclosed herein may also be used to produce multi-crystalline ingots, such as by a directional solidification process.

The crystal growing system 100 includes a crucible support or susceptor 150 supporting a crucible assembly 200 that contains a silicon melt 112 from which an ingot 114 is being pulled by a puller 134. During the crystal pulling process, a seed crystal 132 is lowered by the puller 134 into the melt 112 and then slowly raised or pulled from the melt. As seed crystal 132 is slowly raised from melt 112, the single crystal ingot 114 is formed.

With additional reference to FIG. 2, the crucible assembly 200 includes a first crucible 210 having a first base 212 and a first sidewall 214 and a second crucible 250 having a second base 252 and a second sidewall 254. The respective sidewalls of the crucibles are approximately concentric. Each sidewall 214, 254 extends around the circumference of the respective base 212, 252. The first sidewall 214 and the first base 212 form a first cavity 216. The second sidewall 254 and the second base 252 form a second cavity 256. In some embodiments, the first crucible may have an internal radius of 32-inches and the second crucible may have an internal radius of 24-inches.

At least one crucible passageway 260 extends through the second crucible 250 to allow the melt to move into the second cavity 256 of the second crucible. The crucible passageway 260 may be located along a lower section of sidewall 254 at an elevation below the ultimate melt depth to allow consistent melt levels between the first cavity 216 and the second cavity 256. The highest rate of erosion of the crucible is at the free melt surface, where SiO can evaporate into the purge gas. In some embodiments, the second crucible side wall is of uniform thickness and the melt depth lies within the radius connecting the vertical sidewall smoothly to the base 252. In these embodiments, the crucible is radially thicker and therefore has a longer erosion life.

The second crucible 250 is sized and shaped to allow placement of the second crucible within the first cavity 216 of the first crucible 210. The first base 212 has a top surface 218 and the second base 252 has a bottom surface 258 that are complementary to allow the bottom surface 258 of the second base 252 to rest against the top surface 218 of the first base 212. In some embodiments, the bottom surface of the second base is reshaped to match the top surface of the first base, e.g., by backgrinding or water jet-cutting. In other embodiments, the bottom surface of the second base is manufactured by a crucible fusion process at a vendor with a contour matching the top surface of the first base by dimensional specification.

In some embodiments, the first crucible and the second crucible are bonded together to form a single crucible assembly. The first crucible and the second crucible may be fire polished to improve bonding reliability. Fire polishing increases the OH⁻ content of the quartz, softening it at high temperature and providing a better bond. However, there is no outer bond failure risk because the second crucible is a full, complete crucible. The crucible assembly of this embodiment has a single base and two concentric sidewalls extending upward therefrom.

A cylindrical melt flow barrier or weir 300 is located within the second cavity 256 along the second base 252 at a location inward from the second sidewall 254 to inhibit movement of the melt 112 from a location outward of the weir to a location inward of the weir. The weir 300 includes at least one weir passageway 302 extending therethrough to allow melt in the second cavity 256 to move inward of the weir.

In some embodiments, the weir is a 20-inch quartz cylinder that has a bottom edge shaped to conform to the contacting points of the interior of the 24-inch crucible and is fire polished. In these embodiments, the height of the weir provides necessary clearance to a heat reflector 350. Using a weir that provides a large open inner melt surface area decreases the oxygen level in the ingot. An evaporative oxygen removal subsystem that uses gas flow to remove the oxygen may also be used to reduce the overall level of oxygen within the system.

In some embodiments, the weir is bonded to the second base. In these embodiments, the bonded joint remains cooler than a weir bonded directly to a single, outer crucible, since the bonded joint is not in contact with the hotter first crucible. In some embodiments, the weir passageway and the crucible passageway are unaligned to provide a labyrinth flow or tortuous path for the melt.

An outer zone is formed between the first sidewall 214 and the second sidewall 254. The use of a larger first crucible increases the volume of melt in the outer zone and allows for faster feeding of an intermediate zone, formed between the second sidewall 254 and the weir 300. The intermediate zone allows the solid feedstock material more time to melt as it transitions from the outer zone to the inner zone. The intermediate zone also allows quartz particles, which may be generated in the high temperature outer zone, time to dissolve before reaching the inner zone. An inner zone is formed inward of the weir 300.

The crystal growing system 100 includes the heat reflector 350 adjacent the crucible assembly 200. The heat reflector 350 covers a portion of the first and second cavities 216, 256 and has a cylindrical leg 352 that extends downward between the second sidewall 254 and the weir 300 to form a tortuous gas path. The leg 352 also creates a tortuous path that prevents line-of-sight polysilicon projectiles from reaching the inner melt surface during the addition of the solid feedstock material 116.

In some embodiments, the heat reflector has more than one leg that extends downward at a location inward of the weir and/or downward between the first sidewall and the second sidewall.

Solid feedstock material 116 may be placed into the outer zone from feeder 118 through feed tube 120. The feedstock material 116 is at a much lower temperature than the surrounding melt 112 and absorbs heat from the melt as the feedstock material's temperature rises, and as the solid feedstock material liquefies in the outer zone to form an outer melt portion. As the solid feedstock material 116 (sometimes referred to as “cold feedstock”) absorbs energy from melt 112, the temperature of the surrounding melt falls proportionately to the energy absorbed.

As discussed herein, the system is described in relation to the Czochralski method of producing single crystal ingots. However, the system disclosed herein may also be used to produce multi-crystalline ingots, such as by a directional solidification process.

The amount of feedstock material 116 added is controlled by feeder 118, which is responsive to activation signals from a controller 122. The amount of cooling of the melt 112 is precisely determined and controlled by controller 122. Controller 122 either adds or does not add feedstock material 116 to adjust the temperature and the mass of the melt 112. The addition of feedstock material 116 may be based on the mass of the silicon in the crucible, e.g., by measuring the weight or measuring liquid height of the melt.

As solid feedstock material 116 is added to melt 112, the surface of the melt may be disturbed. This disturbance also affects the ability of the silicon atoms of the melt 112 to properly align with the silicon atoms of the seed crystal 132. The second sidewall 254 and weir 300 inhibit inward propagation of the disturbances, as will be discussed below.

Heat is provided to crucible assembly 200 by one or more heaters 124, 126, and 128 arranged at suitable positions about the crucible assembly. Heat from heaters 124, 126, and 128 initially melt the solid feedstock material 116 and then maintains melt 112 in a liquefied state providing suitable growth conditions for the ingot 114. Heater 124 is generally cylindrical in shape and provides heat to the sides of the crucible assembly 200, and heaters 126 and 128 provide heat to the bottom of the crucible assembly. In some embodiments, heaters 126 and 128 are generally annular in shape. In other embodiments, heaters 126 and 128 are combined into a single heater.

Heaters 124, 126, and 128 are suitably resistive heaters and may be coupled to controller 122. The controller 122 controls electric current provided to the heaters to control heater power delivery and thereby control the feedstock material and melt temperature. A sensor 130, such as a pyrometer or like temperature sensor, provides a continuous measurement of the temperature of melt 112 at the crystal/melt interface of the growing single crystal ingot 114. Sensor 130 also may be configured to measure the temperature of the growing ingot. Sensor 130 is communicatively coupled with controller 122. Additional temperature sensors may be used to measure and provide temperature feedback to the controller with respect to points that are critical to the melting of the feedstock material or in controlling the growing ingot. While a single communication lead is shown for clarity, one or more temperature sensor(s) may be linked to the controller by multiple leads or a wireless connection, such as by an infra-red data link or another suitable means.

The amount of current supplied to each of the heaters 124, 126, and 128 by controller 122 may be separately and independently chosen to optimize the thermal characteristics of melt 112. In some embodiments, one or more heaters may be disposed around the crucible to provide heat.

A second crucible having a full thickness base results in an insulating effect that requires the heaters to produce higher temperatures, which appreciably increase the operational temperature range of the first crucible. At high temperatures, quartz of the crucible breaks down and interacts with graphite from the susceptor to form gaseous carbon monoxide (CO). This gaseous carbon monoxide can cause contamination of the melt. The insulating effect is partially mitigated by the large contact area between the first and second crucible. In some embodiments, the base of the second crucible may be thinned by backgrinding or water-jet reshaping, or second crucibles may be manufactured having a thinner base, to further reduce the required operational temperatures. In some embodiments, the first crucible may be thinned along contact points with the second crucible.

As discussed above, seed crystal 132 is attached to a portion of puller 134 located over melt 112. The puller 134 provides movement of seed crystal 132 in a direction perpendicular to the surface of melt 112 allowing the seed crystal to be lowered down toward or into the melt, and raised up or out of the melt. To produce a high quality ingot 114, the melt 112 in an area adjacent to seed crystal 132/ingot 114 must be maintained at a substantially constant temperature and surface disruptions and foreign solid particles must be minimized.

To limit the surface disturbances and temperature fluctuations in the area immediately adjacent to seed crystal 132/ingot 114, the weir 300 is placed in the second cavity 256 of the second crucible 250. The weir 300 separates the melt 112 into the intermediate melt portion in the intermediate zone and the inner melt portion in the inner zone. The inner melt portion is inward of weir 300 and is adjacent to the seed crystal 132/ingot 114. The intermediate zone provides solid feedstock material more time to be liquefied as the feedstock material transitions from the outer zone to the inner zone. The intermediate zone also allows quartz particles, which may be generated in the high temperature outer zone, time to dissolve before reaching the inner growth zone.

The second sidewall 254 and weir 300 limit movement of melt 112 between the melt intermediate and inner zones. Movement of melt 112 between the zones may be permitted through passageways 260, 302 in lower sections of each of the second crucible 250 and the weir 300, respectively.

The movement of melt 112 is substantially limited to the locations of the passageways 260, 302. Placing the passageways 260, 302 along lower sections of the second sidewall 254 and weir 300 confines the movement of melt 112 to along the bottom of the crucible assembly 200. As a result, any movement of melt 112 into the inner zone is at a location beneath or directly opposite to that of the top of the melt, where ingot 114 is being pulled. This confinement of the melt movement limits surface disruptions and temperature fluctuations along the top of the inner melt portion of the melt 112, which limit dislocations in the forming ingot.

The passageways 260, 302 permit controlled movement of the melt 112 between the outer zone and the intermediate zone and the inner zone. Inhibiting or limiting the melt movement between the melt zones allows the feedstock material in the outer zone to heat to a temperature that is approximately equivalent to the temperature of the inner melt portion as the feedstock material passes into and through the intermediate zone.

The second crucible and the weir 300 are suitably made of quartz, and the melt or feedstock is silicon. In these embodiments, the silicon melt is corrosive and could cause cut-through of the quartz of the second crucible and weir at low pressures to significantly limit the total run time of the system. To prevent excessive erosion of the second crucible and weir which would limit the total run time, oxygen is biased upwards by delivering a supply of argon at a pressure of between about 15 and about 75 Torr, or about 25 Torr or greater and a flow of between about 90 and about 140 SLPM, or less than about 100 SLPM. The higher oxygen content in the melt surface then limits the quartz erosion rate. The higher pressures reduce the velocity of the argon within the system, resulting in a decrease in silicon monoxide being evaporated from the melt surface. Less silicon monoxide is then carried into the exhaust lines preventing the premature blocking of the exhaust lines and early run termination.

The passageways may be aligned to allow controlled flow of the melt from the outer zone, through the intermediate zone, and into the inner zone. In some embodiments, the passageways through the second sidewall may be unaligned with the passageways through the weir to further restrict the flow from the outer zone, through the intermediately zone, and into the inner zone.

In a method of one embodiment for growing a single crystal ingot 114 in a crucible assembly 200 having a first crucible 210 and a second crucible 250, a weir 300 is placed in the second crucible. The area between the first sidewall 214 and the second sidewall 254 defines an outer zone. The area between the second sidewall 254 and the weir 300 defines an intermediate zone. The area inward of the weir 300 defines an inner zone. Feedstock material 116 is placed in the first cavity 216.

Heaters 124, 126 and 128 are placed adjacent to the crucible assembly 200 to provide heat for liquefying or melting the feedstock material 116, forming a melt 112. Once liquefied, the melt 112 moves from the outer zone into the intermediate zone and then into the inner zone. The movement of the melt 112 between the various zones is limited to the passageways 260, 302 through the second crucible 250 and the weir 300.

The seed crystal 132 is lowered into and then slowly raised out of the melt 112 to grow the ingot from the seed crystal. As the seed crystal 132 is slowly raised, silicon atoms from the melt 112 align with and attach to the silicon atoms of the seed crystal 132 allowing the ingot to grow larger and larger. The raising of the silicon atoms from the melt 112 causes them to cool and solidify.

Inhibiting movement of the melt between the zones inhibits or prevents un-liquefied feedstock material from passing into the inner zone and causing a dislocation in the ingot. Unliquefied feedstock may disturb or negatively affect the structural integrity and the crystal structure of the ingot being formed.

In addition, the temperature of the melt increases as the melt passes from the outer zone to the intermediate zone and then into the inner zone. By the time the melt reaches the inner zone, the melt is substantially equivalent in temperature to the melt already in the inner zone. Raising the temperature of the melt before reaching the inner zone reduces the temperature fields within the inner zone. The controller may act to maintain a substantially constant temperature within the inner zone.

Further, inhibiting movement of the melt between the zones to through the passageways allows the surface of the inner zone to remain relatively undisturbed. The weir substantially prevents disturbances in the outer zone or intermediate zone from disrupting the surface of the melt in the inner zone by substantially containing the thermal and mechanical energy waves produced by the disturbances in the outer zone and intermediate zone. The disturbances are also inhibited from passing into the inner zone by the location of the passageways. The passageways are located below the melt top level contact and above the bottom of the second crucible and along the bottom or in a wall of the weir to allow movement of the melt into the inner zone without disrupting the surface stability of the inner zone.

In some embodiments, the temperature of the melt in the inner zone may suitably be measured at a location immediately adjacent the growing ingot by a sensor. In other embodiments, the temperature of the melt in zones other than the inner zone may suitably be measured. The sensor is connected with the controller. The controller adjusts the temperature of the melt by supplying more or less current to the heaters and by supplying more or less feedstock material to the melt. The controller is also capable of simultaneously supplying feedstock material while the seed crystal is raised from the melt and growing the ingot.

Use of the above embodiments reduces oxygen to compensate for an increase in operating pressure to extend run life, lower the consumption rate of the weir, and provide better system performance through slower quartz dissolution. A larger outer zone or feed region prevents icing in the outer feed region, allows for faster feeding and liquefying of the feedstock material in the outer zone and allows higher growth rates of the ingot. The labyrinth flow provides enough time for the solid feedstock material and generated quartz particles in the feed zone to dissolve before reaching the growing ingot. Reducing disturbances in the surface of the melt increases the yield of high zero dislocation (ZD) ingots.

Additionally, use of the above embodiments significantly reduces the risk associated with structural bond failure by the use of a full interior crucible instead of using a second weir. Structural bond failures of a larger weir provide solid feedstock material and quartz generated particles a direct path to the growing crystal at a random azimuthal position degrading performance. The reductions in risk and improved efficiency not only increase the overall production of the crystal forming system, but also lowers overall operational costs.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the invention, it is intended that all matter contained in the above description and shown in the accompanying drawing[s] shall be interpreted as illustrative and not in a limiting sense.

What is claimed is:

1. A system for growing a crystal ingot from a melt, the system comprising:
a first crucible having a first base and a first sidewall forming a first cavity for containing the melt, the first base having a top surface;
a second crucible located within the first cavity of the first crucible having a second base and a second sidewall sized for placement within the first cavity of the first crucible, the second base and the second sidewall forming a second cavity, the second base having a bottom surface that is shaped to allow the second base to rest against the top surface of the first base, the second crucible includes a crucible passageway therethrough to allow the melt in the first cavity of the first crucible to move into the second cavity of the second crucible; and
a weir located along the second base of the second crucible at a location inward from the second sidewall to inhibit movement of the melt from a location outward of the weir to a location inward of the weir.

2. The system of claim 1, further comprising a heater disposed for supplying heat to the first crucible and the second crucible to maintain the melt therein.

3. The system of claim 1, further comprising a feed tube disposed adjacent the first crucible for supplying a feedstock material to the first crucible at a location that is outward of the second crucible.

4. The system of claim 1, wherein the second crucible is bonded to the first crucible to form an assembled crucible having two sidewalls and a single base.

5. The system of claim 1, further comprising a heat reflector having a leg extending downward between the second sidewall of the second crucible and the weir to form a tortuous gas and particle path.

6. The system of claim 1, wherein the weir is bonded to the second base of the second crucible, the weir has a weir passageway extending therethrough to allow the melt in the second cavity of the second crucible to move through the weir.

7. The system of claim 6, wherein the weir passageway and the crucible passageway through the second crucible being unaligned to provide a tortuous path for the melt.

8. The system of claim 1, further comprising a pull system for lowering and raising a seed crystal into and out of the melt.

9. A system for growing a crystal ingot from a melt, the system comprising:
a first crucible having a first base and a first sidewall forming a first cavity for containing the melt;
a second crucible located within the first cavity of the first crucible having a second base and a second sidewall sized for placement within the first cavity of the first crucible, the second base and the second sidewall forming a second cavity, the second crucible includes a crucible passageway therethrough to allow the melt in the first cavity of the first crucible to move into the second cavity of the second crucible;
a weir located within the second cavity of the second crucible to inhibit movement of the melt from a location outward of the weir to a location inward of the weir; and
a heat reflector having a leg extending downward between the second sidewall of the second crucible and the weir to form a tortuous gas and particle path between an inner area being inward of the weir to an outer area being outward of the second sidewall.

10. The system of claim 9, further comprising a heater disposed for supplying heat to the first crucible and the second crucible to maintain the melt therein.

11. The system of claim 9, further comprising a feed tube disposed adjacent the first crucible for supplying a feedstock material to the first crucible at a location that is outward of the second crucible.

12. The system of claim 9, wherein the second crucible is bonded to the first crucible to form an assembled crucible having two sidewalls and a single base.

13. The system of claim 9, wherein the weir is bonded to the second base of the second crucible, the weir has a weir passageway extending therethrough to allow the melt in the second cavity of the second crucible to move within the weir.

14. The system of claim 13, wherein the weir passageway and the crucible passageway through the second crucible being unaligned to provide a tortuous path for the melt.

15. The system of claim 9, further comprising a pull system for lowering and raising a seed crystal into and out of the melt.

16. A method for growing a crystal ingot from a melt in a crystal growing system, the system including a crucible having a base and a first wall extending upward from the base and a second wall extending upward from the base at a location inward from the first wall, wherein the second wall has a passageway to allow the melt to move therethrough, the crucible defining a first cavity between the first wall and the second wall and a second cavity inward of the second wall, the method comprising:
placing a weir within the second cavity to inhibit movement of the melt from a location outward of the weir to a location inward of the weir;
placing feedstock material into the first cavity of the crucible;
melting the feedstock material to form the melt to allow movement of the melt from the first cavity into the second cavity and inward of the weir; and
biasing oxygen upwards on the melt with argon at a pressure of between about 15 and about 70 Torr.

17. The method of claim 16, further comprising the steps of lowering a seed crystal into the melt and raising the seed crystal out of the melt.

18. The method of claim 17, wherein the raising of the seed crystal is performed simultaneously with placing the feedstock material into the first cavity of the crucible.

19. The method of claim 16, further comprising the step of heating the first crucible and second crucible for melting the feedstock material therein.

20. The method of claim 17, wherein the oxygen is biased upwards at a pressure above 25 Torr.
